(19) United States
(12) Patent Application Publication
(10) Pub. No.: US 2015/0200358 A1
(43) Pub. Date: Jul. 16, 2015

(54) SEMICONDUCTOR INTEGRATED CIRCUIT DEVICE HAVING VARIABLE RESISTIVE LAYER AND METHOD OF MANUFACTURING THE SAME

(71) Applicant: SK hynix Inc., Gyeonggi-do (KR)

(72) Inventors: Se Hun KANG, Gyeonggi-do (KR); Jin Ha KIM, Gyeonggi-do (KR); Kang Sik CHOI, Gyeonggi-do (KR); Deok Sin KIL, Gyeonggi-do (KR); Gyu Hyun KIM, Gyeonggi-do (KR); Kyoung Su CHOI, Gyeonggi-do (KR); Sung Bin HONG, Gyeonggi-do (KR); Jung Won SEO, Gyeonggi-do (KR)

(73) Assignee: SK hynix Inc., Gyeonggi-do (KR)

(21) Appl. No.: 14/261,533

(22) Filed: Apr. 25, 2014

(30) Foreign Application Priority Data
Jan. 13, 2014 (KR) 10-2014-0003925

(51) Int. Cl. H01L 45/00; H01L 43/12; H01L 43/02

(52) U.S. Cl. CPC H01L 45/06; H01L 45/1616; H01L 45/147; H01L 45/141; H01L 45/1233; H01L 43/02; H01L 43/12

(57) ABSTRACT

A semiconductor integrated circuit device includes a semiconductor substrate, a lower electrode disposed on the semiconductor substrate wherein an upper surface of the lower electrode has a recess, an interlayer insulating layer disposed on the semiconductor substrate and the lower electrode, the interlayer insulating layer including a variable resistive region exposing the upper surface of the lower electrode, and a variable resistive layer filled in the variable resistive region that contacts the recess of the lower electrode. The variable resistive layer is formed to have an increased width toward a top and a bottom thereof.

### CROSS-REFERENCES TO RELATED APPLICATION

This application claims priority under 35 U.S.C. 119(a) to Korean application No. 10-2014-0003925 filed on Jan. 13, 2014, which is incorporated by reference in its entirety as set forth in full.

### BACKGROUND

1. Technical Field

Various embodiments of the present invention relate to a semiconductor integrated circuit device and a method of manufacturing the same, and more particularly, to a resistive memory device having a variable resistive layer and a method of manufacturing the same.

2. Related Art

With the rapid development of mobile and digital information communication and the consumer-electronic industry, studies on existing electronic charge controlled-devices may reveal limitations. Thus, new functional memory devices having novel concepts other than those in existing electronic charge devices need to be developed. Particularly, next-generation memory devices with large capacities, ultra-high speed, and ultra-low power need to be developed to satisfy demands for large capacity memories of electronic information devices.

Resistive variable memory devices using a resistance material as a memory medium have been suggested as the next-generation memory devices, and typical examples of resistive variable memory devices are phase-change random access memories (PCRAMs), resistance RAMs (ReRAMs), or magnetoresistive RAMs (MRAMs).

A resistive variable memory device may be formed of a switching device and a resistance device, and may store data “0” or “1,” according to a state of the resistance device

Even in the resistive variable memory devices, the first priority is to improve integration density by integrating as many memory cells as possible in a limited small area.

Currently, a variable resistive layer constituting the resistance device is formed in various types. Generally, a method that is primarily used, defines a variable resistive region by forming a through hole in an interlayer insulating layer and burying a phase-change material layer in the variable resistive region.

However, as the integration density of the resistive variable memory device is increased, a diameter or a critical dimension of the variable resistive region is also increasingly reduced. Therefore, there is a need for a method of filling a resistive layer in a narrow variable resistive region without a void.

### SUMMARY

According to an exemplary embodiment of the present invention, a semiconductor integrated circuit device may include a semiconductor substrate, a lower electrode disposed on the semiconductor substrate, wherein an upper surface of the lower electrode has a recess, an interlayer insulating layer disposed on the semiconductor substrate and the lower electrode, the interlayer insulating layer including a variable resistive region exposing the upper surface of the lower electrode, and a variable resistive layer filled in the variable resistive region that contacts the recess of the lower electrode.

According to another embodiment, a semiconductor integrated circuit device may include a semiconductor substrate, a lower electrode disposed on the semiconductor substrate, an interlayer insulating layer disposed on the semiconductor substrate and the lower electrode, the interlayer insulating layer including a variable resistive region exposing the upper surface of the lower electrode, and a variable resistive layer filled in the variable resistive region. The variable resistive region may be formed to have an increased width toward a top and a bottom thereof.

According to another embodiment, a method of manufacturing a semiconductor integrated circuit device may include forming a lower electrode on a semiconductor substrate, forming an interlayer insulating layer on the semiconductor substrate including the lower electrode, forming a hole exposing the lower electrode by etching a portion of the interlayer insulating layer, forming a recess by etching an upper surface of the exposed lower electrode, and forming a variable resistive layer within the hole and the isotropic recess.

These and other features, aspects, and embodiments are described below.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a schematic cross-sectional view illustrating a semiconductor integrated circuit device having a resistance variable characteristic according to an embodiment of the present invention;

FIGS. 2A to 2E are cross-sectional views illustrating a method of manufacturing a semiconductor integrated circuit device according to an embodiment of the present invention;

FIGS. 3A and 3B are cross-sectional views illustrating a method of manufacturing a semiconductor integrated circuit device according to another embodiment of the present invention;

FIGS. 4A to 4C are cross-sectional views illustrating a method of manufacturing a semiconductor integrated circuit device according to an embodiment of the present invention;

FIG. 5 is a perspective view illustrating a semiconductor integrated circuit device manufactured according to an embodiment of the present invention;

FIG. 6 is a block diagram illustrating a microprocessor according to an embodiment of the present invention;

FIG. 7 is a block diagram illustrating a processor according to an embodiment of the present invention; and

FIG. 8 is a block diagram illustrating a system according to an embodiment of the present invention.

### DETAILED DESCRIPTION

Hereinafter, exemplary embodiments ill be described in greater detail with reference to the accompanying drawings. Exemplary embodiments are described herein with reference to cross-sectional illustrations that are schematic illustrations of exemplary embodiments and intermediate structures. As such, variations from the shapes of the illustrations, for example, as a result of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, and intervening layers may also be present. It is also noted that in this specification, “connected/coupled” refers to one component not only directly coupling another component but also indirectly coupling another component through an intermediate component. In addition, a singular form may include a plural form as long as it is not specifically mentioned in a sentence.

The embodiments of the present invention are described herein with reference to cross-section and/or plan illustrations that are schematic illustrations of the present invention. However, embodiments of the present invention should not be limited and construed as limiting the present invention. Although a few exemplary embodiments of the present invention will be shown and described, it will be appreciated by those of ordinary skill in the art that changes may be made in these exemplary embodiments without departing from the principles and spirit of the present invention.

Referring to FIG. 1, a semiconductor integrated circuit device having a resistance variable characteristic may include a lower electrode 110, a variable resistive layer 120, and an upper electrode 125.

The lower electrode 110 may be formed in the first interlayer insulating layer 105 formed on a semiconductor substrate 101. Although not shown in FIG. 1, a switching device may be formed between the semiconductor substrate 101 and the first interlayer insulating layer 105. The lower electrode 110 may include an isotropic recess 110a in an upper surface thereof. The lower electrode 110 may include an impurity-doped polysilicon layer or a metal material. The lower electrode 110 may include a rounded upper surface by the isotropic recess.

The variable resistive layer 120 may be formed in a second interlayer insulating layer 115. The variable resistive layer 120 may be located on the lower electrode 110 including the isotropic recess 110a. The variable resistive layer 120 may include a praseodymium calcium manganese oxide (PCMO) layer for a ReRAM, chalcogenide layer for a PCRAM, a magnetic layer for a MRAM, a magnetization reversal device layer for a spin-transfer torque magnetoresistive RAM (STTMRAM), or a polymer layer for a polymer RAM (PoRAM). The variable resistive layer 120 may be formed to be filled within the isotropic recess 110a of the lower electrode 110.

The second interlayer insulating layer 115 may include a variable resistive region 115a in which the variable resistive layer 120 is to be formed. For example, the variable resistive region 115a may have a through hole exposing the lower electrode 110, and have an increased diameter toward a top thereof.

Therefore, the variable resistive layer 120 may be formed within the variable resistive region 115a increased toward a top thereof to fill the isotropic recess 110a of the lower electrode 110.

The upper electrode 125 may be formed on the variable resistive layer 120.

The variable resistive region 115a may have a narrow diameter due to high integration density of the variable resistive memory device. However, since a bottom of the variable resistive region 115a communicates with the isotropic recess 110a of the lower electrode 110, and the variable resistive region 115a has a structure widened toward the top thereof, the variable resistive layer 120 may be easily deposited.

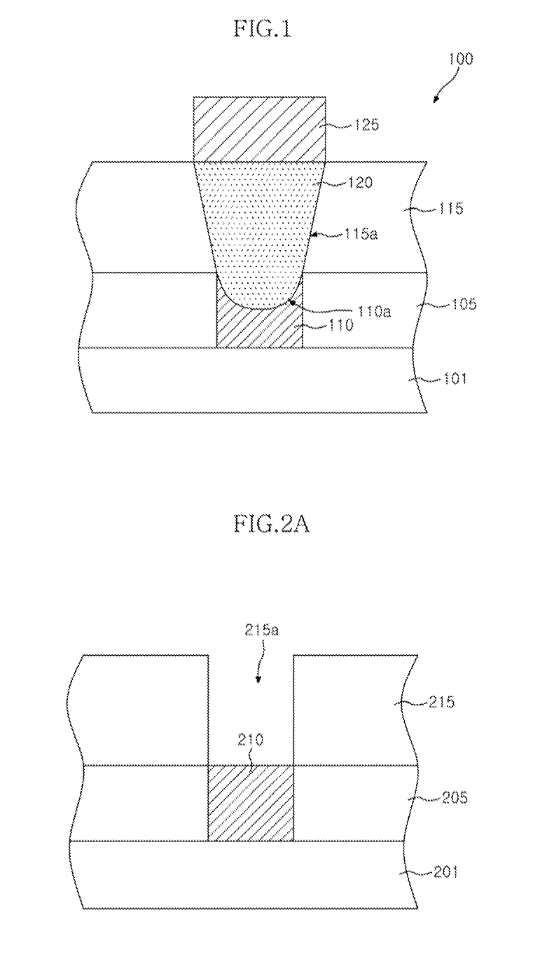

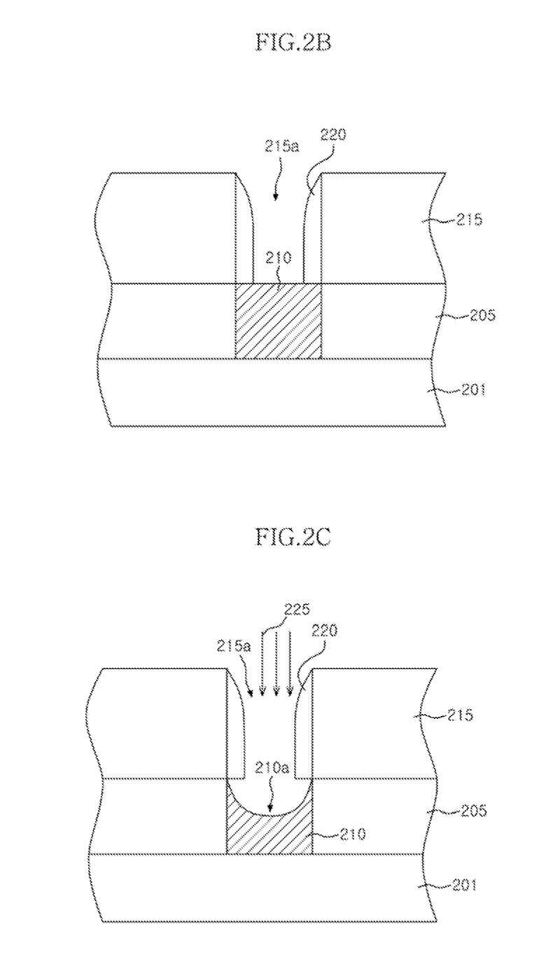

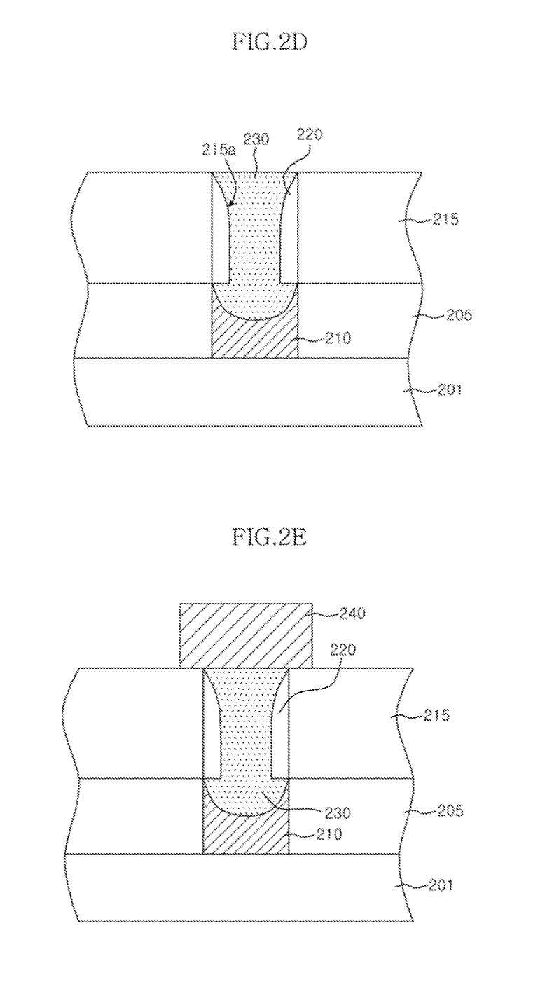

Referring to FIG. 2A, a base insulating layer 205 may be prepared. The base insulating layer 205 may be located on a semiconductor substrate 201 including a switching device (not shown). A lower electrode 210 is formed by forming a through hole (not shown) in the base insulating layer 205 by etching a predetermined portion of the base insulating layer 205, and filling a conductive material within the contract hole. The lower electrode 210 may be electrically coupled to the switching device.

An interlayer insulating layer 215 is deposited on the base insulating layer 205 in which the lower electrode 210 is formed. The interlayer insulating layer 215 is etched to expose a surface of the lower electrode, thereby forming a through hole 215a corresponding to a preliminary variable resistive region.

Referring to FIG. 2B, a spacer 220 may be formed on a sidewall of the through hole 215a using a general method. For example, the spacer 220 may be formed of a silicon nitride material. The variable resistive region 215a having a shape widened toward a top thereof is defined by the formation of the spacer 220.

Referring to FIG. 2C, an isotropic etching process 225 is performed on the lower electrode 210 exposed by the spacer 220 to form an isotropic recess 210a in a surface of the exposed lower electrode 210. The isotropic recess 210a may have a structure in which a bottom thereof is rounded by the isotropic etching process 225. At this time, the isotropic recess 210a may communicate with the variable resistive region 215a.

Referring to FIG. 2D, a variable resistive layer 230 is deposited within the variable resistive region 215a. The variable resistive layer 230 may be deposited using an atomic layer deposition (ALD) method. For example, the variable resistive layer 230 may be deposited in a temperature range of about 200 to 400° C., preferably, about 250 to 300° C. The variable resistive layer 230 deposited in a low temperature by an ALD method may have an amorphous phase. Since the variable resistive region 215a has a narrow critical dimension of a minimum critical dimension level, the variable resistive layer 230 may not be completely filled within the variable resistive region 215a.

Subsequently, a heat treatment may be performed on the variable resistive layer 230 in a low temperature, such as, a crystallization process. The heat treatment process may be performed in a temperature range which can enable reflow of the variable resistive layer 230 and does not affect characteristics of the switching device below the variable resistive layer 230, for example, in the temperature range of about 300 to 600° C. Accordingly, a phenomenon such as the reflow of the variable resistive layer 230 may occur toward the isotropic recess 210a below the variable resistive layer 230, and thus the variable resistive layer 230 may be completely filled in the variable resistive region 215a and the isotropic recess 210a. Therefore, the variable resistive layer 230 is formed in the variable resistive region 215a widened toward a top thereof and the isotropic recess 210a enlarged in a bottom thereof. That is, the variable resistive layer 230 is deposited in a space enlarged upward and downward, and thus, the variable resistive layer is easily deposited without a void as compared to when the variable resistive layer is formed in a variable resistive region having a cylindrical type. Then, the variable resistive layer 230 is planarized.

Referring to FIG. 2E, an upper electrode 240 may be formed on the variable resistive layer 230 through a general process.

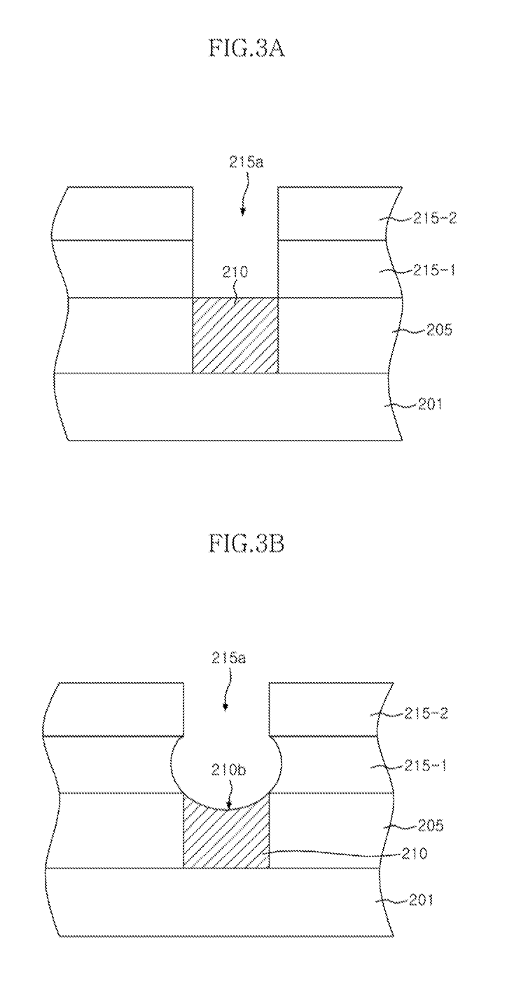

Further, as illustrated in FIG. 3A, an interlayer insulating layer 215 may include a first interlayer insulating layer 215-1 and a second interlayer insulating layer 215-2. The first interlayer insulating layer 215-1 may have different etch selectivity from the second interlayer insulating layer 215-2. Subsequently, a through hole 215a for defining a variable resistive region is formed.

Next, as illustrated in FIG. 3B, the first interlayer insulating layer 215-1 and an exposed lower electrode 210 may be isotropically etched to form an isotropic recess 210b.

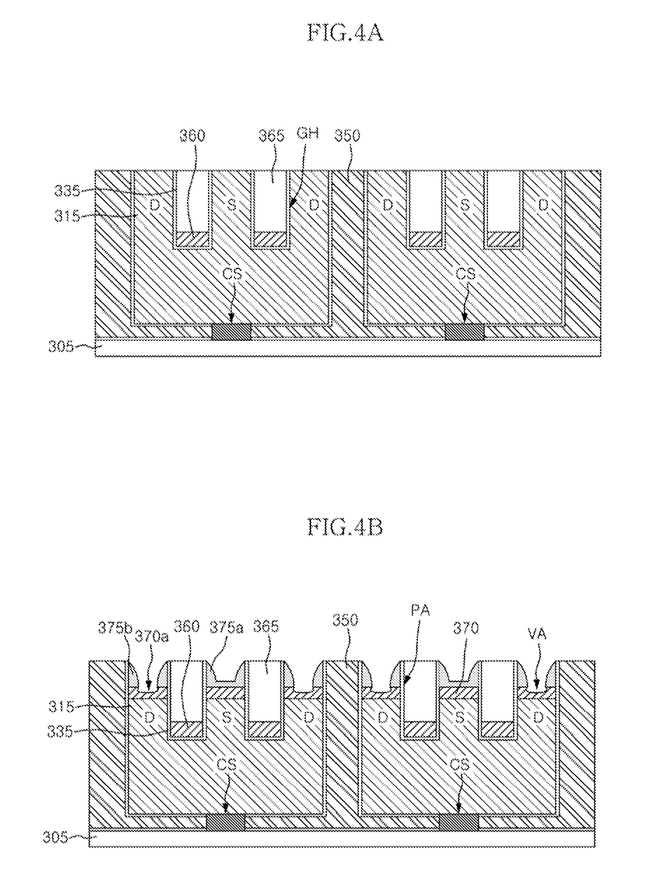

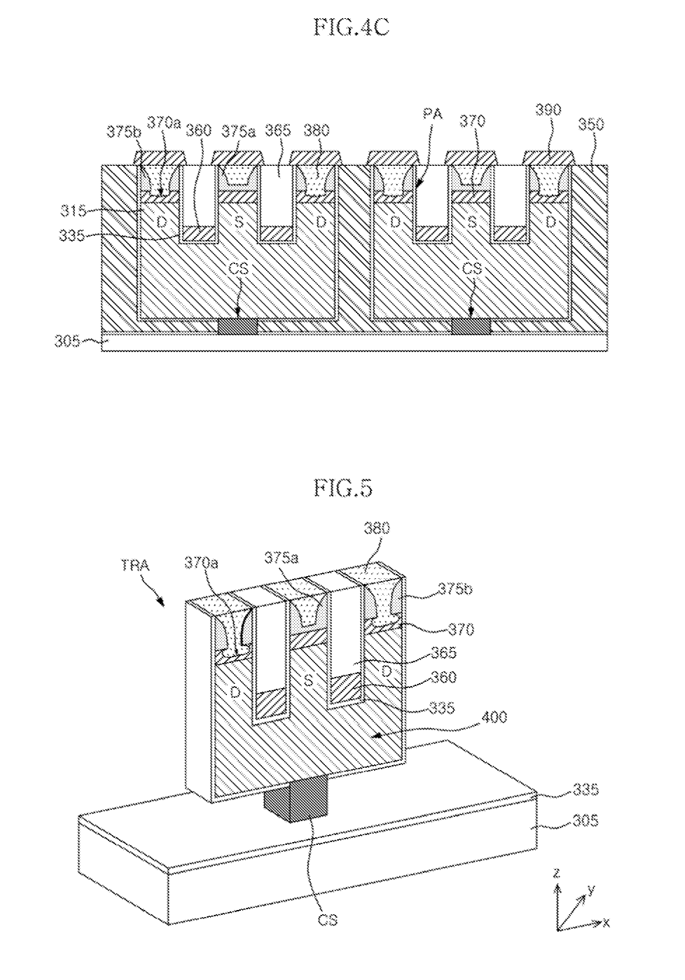

Hereinafter, a method of manufacturing a semiconductor integrated circuit device having a lateral channel switching device according to an embodiment of the present invention will be described with reference to FIGS. 4A to 4C.

Referring to FIG. 4A, an active region 315 supported by a common source region CS is formed on a semiconductor substrate 305. The common source region CS and the active region 315 may be formed of different semiconductor layers. The common source region CS may be a node type or a line type. The common source region CS and the active region 315 may be formed of semiconductor materials having different etch selectivity from each other to define the node or line type common source region CS. In the embodiment, the common source region CS may include a silicon germanium (SiGe) material, and the active region 315 may include a silicon (Si) material.

A gate groove GH is formed in a predetermined region of the active region 315 to define a source region 5 and a drain region D. Portions of the active region 315 at both sides of the gate groove GH may be the source region S and the drain region D. In the embodiment, the source region S and the drain region D are formed so that one source region S is located between a pair of drain regions D. The source region S may be defined in a location of the active region corresponding to the common source region CS.

An oxidation process is performed on the semiconductor substrate including the gate groove GH to form a gate insulating layer 335 on surfaces of the gate groove GH and the active region 315. A gap-fill layer 350 is buried in a space between active regions 315.

A gate electrode 360 is formed in a lower portion of the gate groove GH. The formation of the gate electrode 360 may include forming a conductive layer within the gate groove GH, and overetching the conductive layer to remain in the lower portion of the gate groove GH. After the gate electrode 360 is formed, a sealing insulating layer 365 is filled within the gate groove GH.

As illustrated in FIG. 4B, the source region S and the drain region D at both sides of the gate groove GH are etched to a certain depth to define a preliminary variable resistive region PA. Impurities may be implanted into the source region S and the drain region D exposed by the preliminary variable resistive region PA to define a source and a drain.

Lower electrodes 370 are formed on the source region S and the drain region D in preliminary variable resistive regions PA through a general process. The formation of the lower electrode 370 may include forming a conductive layer to be buried in the preliminary variable resistor regions PA, and recessing the conductive layer to remain in lower portions of the preliminary variable resistive regions PA.

An insulating layer for a spacer is deposited on the semiconductor substrate in which the lower electrodes 370 are formed. An etching process is performed on the insulating layer for a spacer to form a first spacer 375a and a second spacer 375b. The first spacer 375a may be located on the source region S and formed to shield the lower electrode 370 on the source region S. The second spacer 375b may be located on the drain region D, and formed to expose the lower electrode 370 on the drain region D.

Next, the exposed lower electrode 370 is isotropically etched by a certain thickness using the second spacer 375b as a mask to form an isotropic recess 370a in a surface of the lower electrode 370. Therefore, a substantial variable resistive region VA including the isotropic recess 370a is defined on the drain region D.

As illustrated in FIG. 4C, a variable resistive layer 380 is formed to be filled in the variable resistive region VA shown in FIG. 4B The variable resistive layer 380 may be deposited using an ALD method. For example, the variable resistive layer 380 may be deposited in a temperature range of 200 to 400° C., preferably, 250 to 300° C. The variable resistive layer 380 deposited in a low temperature by an ALD method may have an amorphous phase. Subsequently, the variable resistive layer 380 having the amorphous phase may be heat-treated in a low temperature. During the heat treatment process, spread such as reflow of the variable resistive layer 380 may occur toward the isotropic recess 370a below the variable resistive layer 380, and thus, the variable resistive layer 380 may be completely filled in the variable resistive region VA.

Further, the variable resistive region VA has an increased diameter toward a top thereof by the formation of the first or second spacer 375a or 375b and thus, the variable resistive layer 380 may be filled more completely within the variable resistive region VA.

Next, an upper electrode 390 may be formed on the variable resistive layer 380 through a general process,

Referring to FIG. 5, a transistor TRA having a lateral channel is formed on a semiconductor substrate 305 to be supported by a common source region CS.

The transistor TRA may include a lateral channel region 400 and a source region S and a drain region D branched from the lateral channel region 400 in a Z-direction.

The source region S is located to correspond to the common source region CS, and drain regions D are provided at both sides of the source region S so that a pair of drain regions D, share one source region S. The source region S and the drain region D may be spaced apart at certain intervals.

A gate electrode 360 may be located in a space between the source region S and the drain region D, and a gate insulating layer 335 may be located between the gate electrode 360 and each of the source and drain regions S and D and on the substrate 305.

A lower electrode 370 is located on each of the source and drain regions S and D, and the variable resistive layer 380 is located on the lower electrode 370. At this time, the lower electrode 370 on the drain region D may include an isotropic recess 370a in an upper surface thereof.

A first spacer 375a on the source region S may be formed to shield the lower electrode 370 so that the variable resistive layer 380 is electrically insulated from the lower electrode 370.

A second spacer 375b on the drain region D is formed to expose the lower electrode 370 so that the variable resistive layer 380 is in contact with a surface of the isotropic recess 370a of the lower electrode 370. Therefore, the variable resistive layer 380 on the drain region D of the transistor TRA substantially performs a memory operation. Although not shown in FIG. 5, the upper electrode (see 390 of FIG. 4C) may be formed on the variable resistive layer 380.

In the semiconductor integrated circuit device having the above-described structure, the isotropic recess 370a is formed on the surface of the lower electrode 370 to induce the spread of the variable resistive layer 380 downward when the variable resistive layer 380 is formed. Therefore, the variable resistive layer 380 may be formed within the variable resistive region without a void.

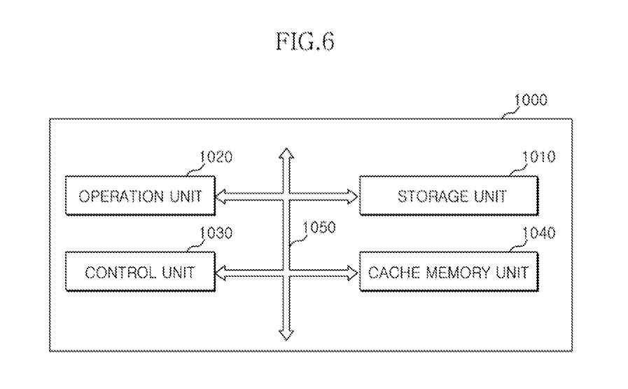

As shown in FIG. 6, a microprocessor 1000 to which the semiconductor device according to the embodiment is applied, may control and adjust a series of processes that receive data from various external apparatuses, process the data, and transmit processing results to the external apparatuses. The microprocessor 1000 may include a storage unit 1010, an operation unit 1020, and a control unit 1030. The microprocessor 1000 may be a variety of processing apparatuses, such as a central processing unit (CPU), a graphic processing unit (GPU), a digital signal processor (DSP), or an application processor (AP).

The storage unit 1010 may be a processor register or a register, and the storage unit may be a unit that may store data in the microprocessor 1000 and include a data register, an address register, and a floating point register. The storage unit 1010 may include various registers other than the above-described registers. The storage unit 1010 may temporarily store data to be operated in the operation unit 1020, resulting data processed in the operation unit 1020, and an address in which the data to be operated is stored.

The storage unit 1010 may include one of the semiconductor devices according to the embodiments of the present invention. The storage unit 1010 including the semiconductor device according to the above-described embodiment may include a semiconductor device including a lower electrode having an isotropic recess. A detailed configuration of the semiconductor device may be the same as the structure of FIG. 1.

The operation unit 1020 may be a unit that may perform an operation in the microprocessor 1000, and perform a variety of four fundamental rules of an arithmetic operation or logic operations depending on a decryption result of a command in the control unit 1030. The operation unit 1020 may include one or more arithmetic and logic units (ALUs).

The control unit 1030 may receive a signal from the storage unit 1010, the operation unit 1020, or an external apparatus of the microprocessor 1000, performs extraction or decryption of a command, or input or output control, and executes a process in a program form.

The microprocessor 1000 according to the embodiment may further include a cache memory unit 1040 that may temporarily store data input from an external apparatus or data to be output to an external apparatus, other than the memory unit 1010. At this time, the cache memory unit 1040 may exchange data with the storage unit 1010, the operation unit 1020, and the control unit 1030 through a bus interface 1050.

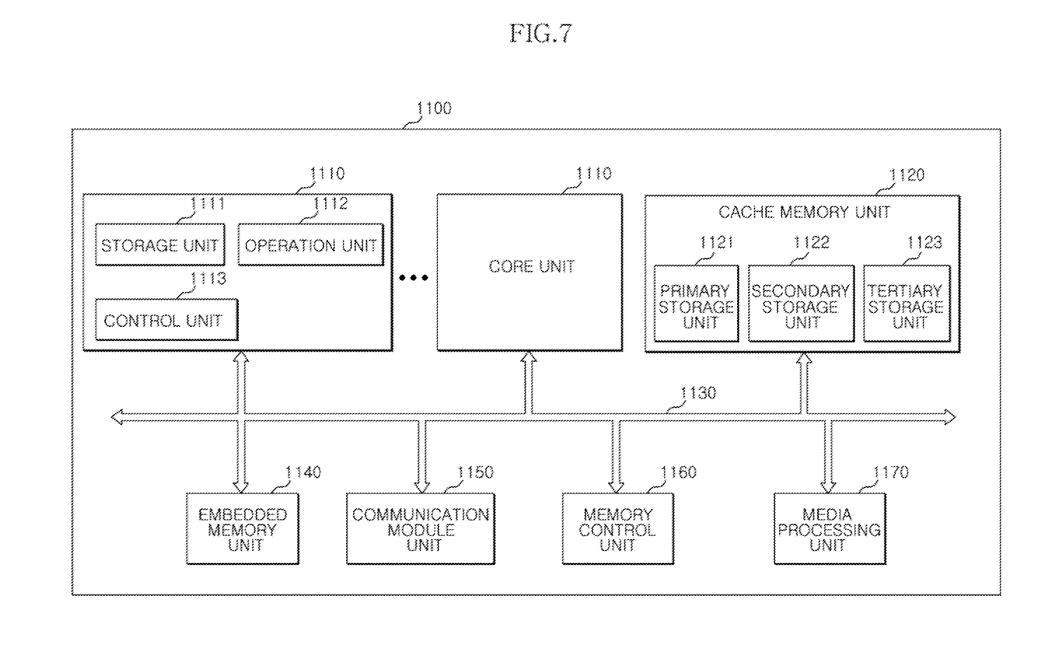

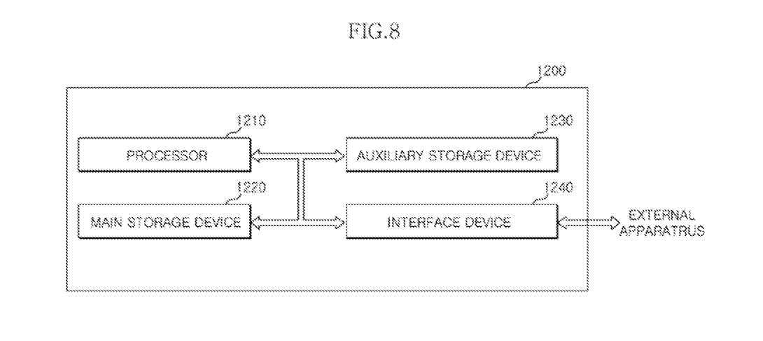

As illustrated in FIG. 7, a processor 1100 to which the semiconductor device according to the embodiment is applied, may include various functions to implement performance improvement and multifunction in addition to the functions of the microprocessor that may control and adjust a series of processes that receive data from various external apparatuses, process the data, and transmit processing results to the external apparatuses. The processor 1100 may include a core unit 1110, a cache memory unit 1120, and a bus interface 1130. The core unit 1110 in the embodiment may be a unit that may perform arithmetic and logic operations on data input from an external apparatus, and include a storage unit 1111, an operation unit 1112, and a control unit 1113. The processor 1100 may be a variety of system on chips (SoCs) such as a multi core processor (MCP), a graphics processing unit (GPU) or an application processor (AP).

The storage unit 1111 may be a processor register or a register, and the storage unit 1111 may be a unit that may store data in the processor 1100 and include a data register, an address register, and a floating point register. The storage unit 1111 may include various registers other than the above-described registers. The storage unit 1111 may temporarily store data to be operated in the operation unit 1112, resulting data processed in the operation unit 1112, and an address in which the data to be operated is stored. The operation unit 1112 may be a unit that may perform an operation in the processor 1100, and perform a variety of four fundamental rules of an arithmetic operation or logic operations depending on a decryption result of a command in the control unit 1113. The operation unit 1112 may include one or more arithmetic and logic units (ALUs). The control unit 1113 receives a signal from the storage unit 1111, the operation unit 1112, or an external apparatus of the processor 1100, performs extraction or decryption of a command, or input or output control, and executes a process in a program form.

The cache memory unit 1120 may be a unit that may temporarily store data to supplement a data processing rate of a low speed external apparatus unlike the high speed core unit 1110. The cache memory unit 1120 may include a primary storage unit 1121, a secondary storage unit 1122, and a tertiary storage unit 1123. In general, the cache memory unit 1120 may include the primary and secondary storage units 1121 and 1122. When a high capacity storage unit is necessary, the cache memory unit 1120 may include the tertiary storage unit 1123. If necessary, the cache memory 1120 may include more storage units. That is, the number of storage units included in the cache memory unit 1120 may be changed according to design. Here, processing rates of data storage and discrimination of the primary, secondary, and tertiary storage units 1121, 1122, and 1123 may be the same as or different from each other. When the processing rates of the storage units are different, the processing rate of the primary storage unit is the greatest. One or more of the primary storage unit 1121, the secondary storage unit 1122, and the tertiary storage unit 1123 in the cache memory unit 1200 may include one of the semiconductor devices according to the embodiments of the present invention.

The cache memory unit 1120 including the semiconductor device according to the above-described embodiment may include a semiconductor device including a lower electrode having an isotropic recess. A detailed configuration of the semiconductor device may be the same as the structure of FIG. 1.

FIG. 7 has illustrated that all of the primary, secondary and tertiary storage units 1121, 1122, and 1123 are disposed in the cache memory unit 1120. However, all of the primary, secondary and tertiary storage units 1121, 1122, and 1123 in the cache memory unit 1120 may be disposed outside the core unit 1110, and may supplement a difference between the processing rates of the core unit 1110 and an external apparatus. Further, the primary storage unit 1121 of the cache memory unit 1120 may be located in the core unit 1110, and the secondary storage unit 1122 and the tertiary storage unit 1123 may be located outside the core unit 1110 to further enforce a function that compensates a processing rate.

The bus interface 1130 may be,a unit that may couple the core unit 1110 and the cache memory unit 1120 to efficiently transmit data.

The processor 1100 according to the embodiment of the present invention may include a plurality of core units 1110, and the core units 1110 may share the cache memory unit 1120. The core units 1110 and the cache memory unit 1120 may be coupled through the bus interface 1130. The core units 1110 may have the same configuration as the configuration of the above-described core unit 1110. When the core units 1110 are provided, the primary storage unit 1121 of the cache memory unit 1120 may be disposed in each of the core units 1110 corresponding to the number of core units 1110, and one secondary storage unit 1122 and one tertiary storage unit 1123 may be disposed outside the core units 1110 so that the core units share the secondary and tertiary storage units through the bus interface 1130. Here, the processing rate of the primary storage unit 1121 may be greater than those of the secondary and tertiary storage units 1122 and 1123.

The processor 1100 according to the embodiment of the present invention may further include an embedded memory unit 1140 that may store data, a communication module unit 1150 that may transmit and receive data to and from an external apparatus in a wired manner or a wireless manner, a memory control unit 1160 that may drive an external storage device, and a media processing unit 1170 that may process data processed in the processor 1100 or data input from an external apparatus and may output a processing result to an external interface device. The processor may further include a plurality of modules other than the above-described modules. At this time, the additional modules may transmit data to and receive data from the core unit 1110 and the cache memory unit 1120, and transmit and receive data between the modules through the bus interface 1130.

The embedded memory unit 1140 may include a volatile memory or a nonvolatile memory. The volatile memory may include a dynamic random access memory (DRAM), a mobile DRAM, a static RAM (SRAM), or the like, and the nonvolatile memory may include a read only memory (ROM), a NOR flash memory, a NAND flash memory, a phase-change RAM (PRAM), a resistive RAM (RRAM), a spin transfer torque RAM (STTRAM), a magnetic RAM (MRAM) or the like. The semiconductor device according to the embodiment of the present invention may be applied to the embedded memory unit 1140.

The communication module unit 1150 may include all modules such as a module coupled to a wired network and a module coupled to a wireless network. The wired network module may include a local area network (LAN), a universal serial bus (USB), Ethernet, power line communication (PLC), or the like, and the wireless network module may include Infrared Data Association (IrDA), Code Division Multiple Access (CDMA), Time Division Multiple Access (TDMA), Frequency Division Multiple Access (FDMA), a wireless LAN, Zigbee, a Ubiquitous Sensor Network (USN), Bluetooth, Radio Frequency Identification (RFID), Long Term Evolution (LTE), Near Field Communication (NFC), Wireless Broadband Internet (Wibro), High Speed Downlink Packet Access (HSDPA), Wideband CDMA (WCDMA), Ultra WideBand (UWB), or the like.

The memory control unit 1160 may be a unit that manages data transmitted between the processor 1100 and an external apparatus that may operate according to a different communication standard from the processor 1100. The memory control unit 1160 may include a variety of memory controllers, or a controller that may control Integrated Device Electronics (IDE), Serial Advanced Technology Attachment (SATA), a Small Computer System Interface (SCSI), a Redundant Array of Independent Disks (RAID), a solid state disk (SSD), External SATA (eSATA), Personal Computer Memory Card International Association (PCMCIA), a USB, a secure digital (SD) card, a mini secure digital (mSD) card, a micro SD card, a secure digital high capacity (SDHC) card, a memory stick card, a smart media (SM) card, a multimedia card (MMC), an embedded MMC (eMMC), a compact flash (CF) card, or the like.

The media processing unit 1170 may be a unit that may process data processed in the processor 1100 or data input from an external input device and may output a processing result to an external interface device so that the processing result may be transferred in video, sound, or other types. The media processing unit 1170 may include a GPU, a DSP, a HD audio, a high definition multimedia interface (HDMI) controller, or the like,

As illustrated in FIG. 8, a system 1200 to which the semiconductor device according to an embodiment of the present invention is applied, is a data processing apparatus. The system 1200 may perform input, processing, output, communication, storage, and the like to perform a series of operations on data, and include a processor 1210, a main storage device 1220, an auxiliary storage device 1230, and an interface device 1240. The system according to the embodiment may be a variety of electronic systems that may operate using a processor, such as a computer, a server, a personal digital assistant (PDA), a portable computer, a web tablet, a wireless phone, a mobile phone, a smart phone, a digital music player, a portable multimedia player (PMP), a camera, a global positioning system (GPS), a video camera, a voice recorder, Telematics, an audio visual (AV) system, or a smart television.

The processor 1210 is a core configuration of the system that may control interpretation of an input command and processing such as an operation, comparison, and the like of data stored in the system, and may include a MPU, a CPU, a single/multi core processor, a GPU, an AP, a DSP, or the like.

The main storage unit 1220 is a storage place that may receive a program or data from the auxiliary storage device 1230 and execute the program or the data when the program is executed. The main storage device 1220 retains the stored content even in power off, and may include the semiconductor device according to the above-described embodiment. The main storage device 1220 may include a semiconductor device including a lower electrode having an isotropic recess. A detailed configuration of the semiconductor device may be the same as the structure of FIG. 1.

The main storage device 1220 according to the embodiment of the present invention may further include an SRAM or a DRAM of a volatile memory type in which all contents are erased when power is off. Alternatively, the main storage device 1220 may not include the semiconductor device according to the embodiment but may include an SRAM or a DRAM of a volatile memory type in which all contents are erased when power is off.

The auxiliary storage device 1230 is a storage device that may store a program code or data. The auxiliary storage device 1230 may have a lower data processing rate than that of the main storage device 1220, but may store a large amount of data and include the semiconductor device according to the above-described embodiment. The auxiliary storage unit 1230 may include a semiconductor device including a lower electrode having an isotropic recess. A detailed configuration of the semiconductor device may be the same as the structure of FIG. 1.

An area of the auxiliary storage device 1230 according to the embodiment may be reduced to reduce the system 1200 size and increase portability of the system 1200. Further, the auxiliary storage device 1230 may further include a data storage system (not shown), such as a magnetic tape or a magnetic disc using a magnetism, a laser disc using light, a magneto-optical disc using a magnetism and light, an SSD, a USB memory, a SD card, a mSD card, a micro SD card, a SDHC card, a memory stick card, a SM card, a MMC, an eMMC, or a CF card. Alternatively, the auxiliary storage device 1230 may not include the semiconductor device according to the above-described embodiment but may include a data storage system (not shown), such as a magnetic tape or a magnetic disc using a magnetism, a laser disc using light, a magneto-optical disc using a magnetism and light, an SSD, a USB memory, a SD card, a mSD card, a micro SD card, a SDHC card, a memory stick card, a SM card, a MMC, an eMMC, or a CF card.

The interface device 1240 may exchange a command and data of an external apparatus with the system of the embodiment, and may be a keypad, a keyboard, a mouse, a speaker, a microphone, a display, a variety of Human Interface Devices (HIDs), or a communication device. The communication device may include all modules such as a module coupled to a wired network and a module coupled to a wireless network. The wired network module may include a LAN, a USB, Ethernet, PLC, or the like, and the wireless network module may include IrDA, CDMA, TDMA, FDMA, a wireless LAN, Zigbee, a USN, Bluetooth, RFID, LTE, NFC, Wibro, HSDPA, WCDMA, UWB, or the like.

The above embodiments of the present invention are illustrative and not limitative. Various alternatives and equivalents are possible. The invention is not limited by the embodiment described herein, nor is the invention limited to any specific type of semiconductor device. Other additions, subtractions, or modifications are obvious in view of the present disclosure and are intended to fall within the scope of the appended claims.

What is claimed is:

1. A semiconductor integrated circuit device, comprising:
a semiconductor substrate;
a lower electrode disposed on the semiconductor substrate, wherein an upper surface of the lower electrode has a recess;
an interlayer insulating layer disposed on the semiconductor substrate and the lower electrode, the interlayer insulating layer including a variable resistive region exposing the upper surface of the lower electrode; and a variable resistive layer filled in the variable resistive region, wherein the variable resistive layer is formed along the upper surface of the lower electrode having the recess.

2. The semiconductor integrated circuit device of claim 1, wherein the recess in the upper surface of the lower electrode is an isotropic recess.

3. The semiconductor integrated circuit device of claim 1, wherein the variable resistive region is formed to have an increased width toward a top thereof.

4. The semiconductor integrated circuit device of claim 1, further comprising:
an insulating spacer disposed on a sidewall of the variable resistive region.

5. The semiconductor integrated circuit device of claim 1, wherein the variable resistive layer includes a praseodymium calcium manganese oxide (PCMO) layer for a resistance random access memory (ReRAM), a chalcogenide layer for a phase-change RAM (PCRAM), a magnetic layer for a magnetic MRAM (MRAM), a magnetization reversal device layer for a spin-transfer torque magnetoresistive RAM (STTMRAM), or a polymer layer for a polymer RAM (PoRAM).

6. The semiconductor integrated circuit device of claim 1, further comprising:
an upper electrode disposed on the variable resistive layer.

7. A semiconductor integrated circuit device, comprising:
a semiconductor substrate;
a lower electrode disposed on the semiconductor substrate;
an interlayer insulating layer disposed on the semiconductor substrate and the lower electrode, the interlayer insulating layer including a variable resistive region exposing the upper surface of the lower electrode; and a variable resistive layer filled in the variable resistive region, wherein the variable resistive region is formed to have an increased width toward a top and a bottom thereof.

8. The semiconductor integrated circuit device of claim 7, wherein the interlayer insulating layer includes:
first interlayer insulating layer disposed on the lower electrode; and
a second interlayer insulating layer disposed on the first interlayer insulating layer.

9. The semiconductor integrated circuit device of claim 8, wherein the first interlayer insulating layer and the upper surface of the lower electrode has a recess over a sidewall of the first interlayer insulating layer and an upper surface of the lower electrode.

10. The semiconductor integrated circuit device of claim 9, wherein the recess of the upper surface of the lower electrode is an isotropic recess.

11. The semiconductor integrated circuit device of claim 7, further comprising:
an insulating spacer disposed on a sidewall of the variable resistive region.

12. The semiconductor integrated circuit device of claim 7, wherein the variable resistive layer includes a praseodymium calcium manganese oxide (PCMO) layer for a resistance random access memory (ReRAM), a chalcogenide layer for a phase-change RAM (PCRAM), a magnetic layer for a magnetic MRAM (MRAM), a magnetization reversal device layer for a spin-transfer torque magnetoresistive RAM (STTMRAM), or a polymer layer for a polymer RAM (PoRAM).

13. A method of manufacturing a semiconductor integrated circuit device, comprising:
forming a lower electrode on a semiconductor substrate;
forming an interlayer insulating layer on the semiconductor substrate including the lower electrode;
forming a hole exposing the lower electrode, by etching a portion of the interlayer insulating layer;
forming a recess by etching an upper surface of the exposed lower electrode; and
forming a variable resistive layer within the hole and the isotropic recess.

14. The method of claim 13, further comprising:
forming an insulating spacer on a sidewall of the hole between the forming of the hole and the forming of the isotropic recess.

15. The method of claim 13, wherein the forming of the interlayer insulating layer includes:
forming a first interlayer insulating layer on the lower electrode; and
forming a second interlayer insulating layer having different etch selectivity from the first interlayer insulating layer on the first interlayer insulating layer.

16. The method of claim 15, further comprising:
isotropically etching a sidewall of the first interlayer insulating layer between the forming of the hole and the forming of the isotropic recess.

17. The method of claim 16, wherein the forming of the variable resistive layer includes:
forming a variable resistive material in the variable resistive region; and
performing a heat treatment on the variable resistive material to reflow and fill the hole and the isotropic recess.

18. The method of claim 17, wherein the variable resistive material is deposited through an atomic layer deposition (ALD) method.
